(19) United States
(12) Patent Application Publication
(10) Pub. No.: US 2014/0234773 A1
(43) Pub. Date: Aug. 21, 2014

(54) METHOD OF COATING RESIST AND RESIST COATING APPARATUS

(71) Applicant: Kabushiki Kaisha Toshiba, Minato-ku (JP)

(72) Inventors: Katsunori SUZUKI, Mie-ken (JP); Seiji Nakagawa, Mie-ken (JP); Hiroharu Fujise, Mie-ken (JP)

(73) Assignee: Kabushiki Kaisha Toshiba, Minato-ku (JP)

(21) Appl. No.: 14/180,685

(22) Filed: Feb. 14, 2014

(30) Foreign Application Priority Data
Feb. 15, 2013 (JP) 2013-028421

(51) Int. Cl. G03F 7/16

(52) U.S. Cl. CPC G03F 7/162
USPC 430/270.1; 118/52; 118/712

(57) ABSTRACT

An aspect of the present embodiment, there is provided a method of coating resist, including providing solvent on a substrate to be processed being set to be nearly still, and rotating the substrate to be processed to provide resist solution on the substrate to be processed from a resist supply nozzle in a state that a top edge of the resist supply nozzle is inserted into the solvent.

### CROSS REFERENCE TO RELATED APPLICATION

This application is based upon and claims the benefit of priority from prior Japanese Patent Application No. 2013-028421, filed on Feb. 15, 2013, the entire contents of which are incorporated herein by reference.

### FIELD

Exemplary embodiments described herein generally relate to a method of costing resist and a resist coating apparatus.

### BACKGROUND

Generally, patterning process to form a prescribed pattern is included in fabricating process of a semiconductor device. The patterning is performed after forming a film to be processed on a substrate to be processed. In the patterning process, resist solution is coated by spin-coating to form the resist as a photo sensitive material. Subsequently, the resist film is exposed with light and is developed with developer for processing the resist film to be patterned as a prescribed pattern. A large amount of the resist is used in the coating of the resist solution. Accordingly, an amount of the resist solution used in the processing steps is desired to be decreased.

It is necessary to be suppressed that a resist supply nozzle providing the resist is contacted to the substrate W to be processed when the resist solution is coated on the substrate to be processed. Therefore, the resist solution has been conventionally provided in a state that the resist supply nozzle is separated from the substrate to be processed in a prescribed distance. In such a case, when pressure applied to the resist solution in the resist supply nozzle, the resist solution is continuously supplied from a top edge of the resist supply nozzle to the substrate to be processed.

However, the pressure applied to the resist solution in the resist supply nozzle is decreased when a supply amount of the resist solution is decreased for effectively utilizing the resist solution. In such the situation, the resist solution cannot be continuously supplied and may be supplied on and off.

### BRIEF DESCRIPTION OF THE DRAWINGS

FIG. 1 is a cross-sectional view schematically showing a resist coating apparatus according to an embodiment;

FIG. 2 is a block diagram showing the resist coating apparatus according to the embodiment;

FIG. 3A is a view showing a first step in a method of coating the resist according to the embodiment;

FIG. 3B shows a step in the method of coating the resist where the supply nozzle approaches the center of the substrate;

FIG. 3C shows a further step in the method of coating the resist; and

FIG. 3D shows a yet further step in the method of coating the resist.

### DETAILED DESCRIPTION

An aspect of the present embodiment, there is provided a method of coating resist, including providing solvent on a substrate to be processed being set to be nearly still, and rotating the substrate to be processed to provide resist solution on the substrate to be processed from a resist supply nozzle in a state that a top edge of the resist supply nozzle is inserted into the solvent.

Another aspect of one embodiment, there is provided a resist coating apparatus, including a substrate holding member configured to nearly horizontally retain the substrate to be processed, a rotation unit configured to rotate the substrate holding member, a solvent supply nozzle configured to provide solvent to the substrate to be processed, a resist solution supply nozzle to be configured to provide resist solution to the substrate W to be processed herein the resist solution is provided on the substrate to be processed from the resist supply nozzle in rotating the substrate to be processed by the rotation unit in a state that a top edge of the resist solution supply nozzle is inserted into the solvent on the substrate to be processed provided from the solvent supply nozzle.

### Embodiment

Embodiments will be described below in detail with reference to the attached drawings mentioned above. Throughout the attached drawings, similar or same reference numerals show similar, equivalent or same components, and the description is not repeated.

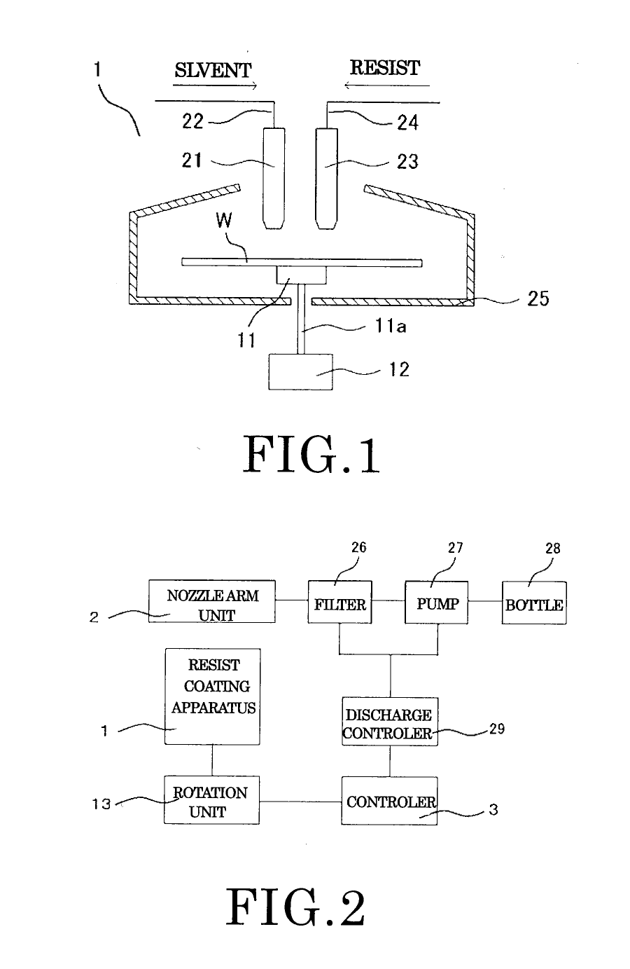

First, a resist coating apparatus according to an embodiment is described below. FIG. 1 is a schematic drawing of the resist coating apparatus according to the embodiment;

A substrate holding member 11 is placed in a resist coating apparatus 1. The substrate holding member 11 nearly horizontally retains the substrate W to be processed by vacuum absorption. The substrate holding member 11 is constituted with a spin chuck, for example. A rotational axis 11a is placed in the substrate holding member 11.

A substrate rotation unit 12 is placed at an under side of the substrate holding member 11 to connect to the rotational axis 11a. The substrate rotation unit 12 rotates the substrate holding member 11 to rotate the substrate W to be processed retained on the substrate holding member 11. The substrate rotation unit 12 is constituted with a driving motor, for example, a pulse motor or the like, and can arbitrarily control a rotational speed.

A solvent supply nozzle 21 is placed in the resist coating apparatus 1 and supplies solvent 4 at nearly the center of a surface of the substrate W to be processed. The solvent 4 is supplied so that the surface of the substrate W to be processed is easily wet with the resist solution before coating the resist on the substrate W to be processed. The solvent 4 is composed of solution, pre-wetted with thinner, including cyclohexane, for example. The solvent 4 is supplied from a solvent supply pipe 22 connected to the solvent supply nozzle 21. Supplying of the solvent 4 to the substrate W to be processed is described below.

A resist supply nozzle 23 is placed in the resist coating apparatus 1 and supplies resist solution at nearly the center of the surface of the substrate W to be processed. The resist solution is coated in a state that the substrate W to be processed is rotated after the solvent is coated on the substrate W to be processed. The resist solution is supplied from a resist supply pipe 24 connected to the resist supply nozzle 23.

A cup 25 is placed in the resist coating apparatus 1 to prevent scattering of the resist solution or the like. The cup 25 has an opening at the center of each of an upper portion and a bottom portion. Spaces at an upper portion, a lower portion and a surrounded portion of the substrate W to be processed are surrounding with the cup 25. The opening of the upper portion of the cup 25 is set as a space where the solvent supply nozzle 21 and the resist supply nozzle 23 are movable. In the opening of the bottom portion of the cup 25, the substrate holding member 11 and the substrate rotation unit 12 are placed.

FIG. 2 is a block diagram showing the resist coating apparatus 1 according to the embodiment. The solvent 4 and the resist solution supplied to the substrate W to be processed are contained in each of bottles 28 for the solvent and the resist solution, respectively.

A pump 27 connected to the bottles 28 pumps up each solution from the bottle corresponding to supplying of each solution. A filter 26 is provided at a down stream side of the pump to remove impurities or the like in each solution. Each of the solvent and the resist solution passed through the filter 26 is supplied to solvent supply nozzle 21 and the resist supply nozzle 23, respectively. The pump 27 and the filter 26 are controlled by a discharge control unit 29. Accordingly, a supply amount supplied of each solution to the substrate W to be processed can be suitably selected. Furthermore, the resist coating apparatus 1 can include a thickness measurement unit (not shown) to measure a thickness of the solvent.

A nozzle arm unit 2 includes the solvent supply nozzle 21, the resist supply nozzle 23 and a nozzle arm driving unit (not shown) to drive the solvent supply nozzle 21 and the resist supply nozzle 23. The nozzle arm driving unit transfers the solvent supply nozzle 21 and the resist supply nozzle 23 onto the substrate W to be processed.

The rotation control unit 13 is placed to contact to the substrate rotation unit 12 rotating the substrate W to be processed to control start and end of the rotation and rotation number or the like of the substrate W to be processed.

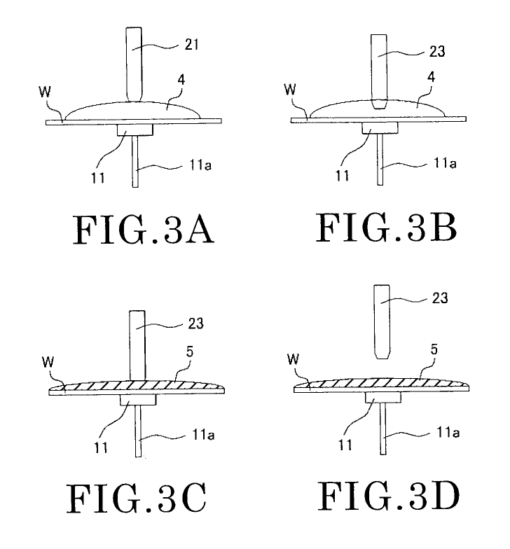

A controller 3 controls the discharge unit 29, the rotation control unit 13 and the nozzle arm driving unit in conjunction with each other. Next, a method of coating resist according to the embodiment is explained by using a cross-sectional view in FIG. 3.

As shown in FIG. 3A, the solution including solvent 4 with an amount of 2.5 cc including cyclohexane, for example, is coated on nearly the center portion of the substrate W to be processed retained by the substrate holding unit from the solvent supply nozzle 21. The thinner is coated so that a surface of a semiconductor wafer as the substrate W to be processed is easily wetted. In such the state, a little amount of the resist solution can be supplied on whole surface of the substrate W to be processed described below. Coating of the solvent 4 is conducted without rotation of the substrate W to be processed to be set nearly still. In such a manner, a layer of the solvent 4 is mounted on the thinner. As described after, a top edge of the resist supply nozzle 23 is easily inserted into the solvent on the substrate W to be processed. Namely, it can be suppressed that the surface of the substrate to be processed is scratched due to the contact between the substrate W to be processed and the resist supply nozzle 23. A height of the solvent is desired to be less than 1 mm when the solvent 4 is coated on the substrate W to be processed

As shown in FIG. 3B, the resist supply nozzle 23 is approached to nearly the center portion of the substrate W to be processed. The top edge of the resist supply nozzle 23 is inserted into the solvent on the substrate W to be processed. In this case, it is desired that the substrate W to be processed is set to be nearly still. The height of the solvent 4 is changed by drying or evaporating. Therefore, it is desired that a position of the resist supply nozzle 23 is preliminarily determined according to height measurement.

The resist solution is coated from the resist supply nozzle 23 on the substrate W to be processed. The substrate W to be processed is rotated at nearly the same as the coating of the resist solution by using the substrate rotation unit 12. A coating amount of the resist solution is set to be 0.70 cc, for example, and the rotation speed of the substrate W to be processed is set to be 2,500 rpm. In such a manner, the resist solution is supplied on the whole surface of the substrate W to be processed. The top edge of the resist supply nozzle 23 is desired to be inserted in the solvent 4 on the substrate W to be processed until finishing the coating of the resist solution. Accordingly, a thickness of a resist 5 in thinned by the rotation of the substrate W to be processed as the solvent 4 on the substrate W to be processed is thinned. Therefore, a distance between the top edge of the resist supply nozzle 23 and the surface of the substrate W to be processed is controlled corresponding to time from the start of the rotation. The distance is desired to be decreased, for example.

Next, after finishing the supply of the resist solution, the rotation of the substrate W to be processed is stopped. Further, the resist supply nozzle 23 is separated from the substrate W to be processed and the resist supply nozzle 23 is returned to a prescribed position. In processing steps described above, the coating of the resist 5 on the substrate W to be processed according to the embodiment is completed.

As mentioned above, the resist solution is provided from the resist supply nozzle according to the embodiment in a state that the resist supply nozzle is inserted into the solvent coated on the substrate to be processed. In such a manner, the resist solution can be continuously supplied on the substrate to be processed, even when a small amount of the resist solution is supplied.

Furthermore, the solvent is supplied onto the substrate to be processed in a state that substrate to be processed is set to be nearly still. In such a manner, thicker solvent can be coated. As a result, the resist supply nozzle is not approached to so near the substrate to be processed, the solvent can be inserted into the solvent.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method of coating of a resist, comprising:
providing solvent on a substrate to be processed being set to be nearly still; and
rotating the substrate to be processed to provide resist solution on the substrate to be processed from a resist supply nozzle in a state that a top edge of the resist supply nozzle is inserted into the solvent.

2. The method of claim 1, wherein
a position of the resist supply nozzle is controlled corresponding to a variation of a thickness of the solvent.

3. The method of claim 2, wherein
the resist supply nozzle is approached to the substrate W to be processed with decreasing the thickness of the solvent.

4. The method of claim 1, wherein
the solvent includes cyclohexane.

5. The method of claim 1, further comprising:
the thickness of the solvent is measured after the providing of the solvent and before the providing of the resist solution.

6. The method of claim 5, wherein
the thickness of the solvent is not less than 1 mm.

7. A resist coating apparatus, comprising:
a substrate holding member configured to nearly horizontally retain the substrate to be processed;
a rotation unit configured to rotate the substrate holding member;
a solvent supply nozzle configured to provide solvent to the substrate to be processed;
a resist solution supply nozzle to be configured to provide resist solution to the substrate to be processed;
wherein the resist solution is provided on the substrate to be processed from the resist supply nozzle in rotating the substrate to be processed by the rotation unit, in a state that a top edge of the resist solution supply nozzle is inserted into the solvent on the substrate to be processed provided from the solvent supply nozzle.

8. The resist coating apparatus of claim 7, further comprising:
a nozzle arm unit configured to drive the solvent supply nozzle and the resist solution supply nozzle.

9. The resist coating apparatus of claim 8, wherein
a position of the resist supply nozzle is controlled corresponding to a variation of a thickness of the solvent.

10. The resist coating apparatus of claim 8, wherein
the resist supply nozzle is approached to the substrate to be processed by the nozzle arm unit with decreasing the thickness of the solvent.

11. The resist coating apparatus of claim 7, wherein
the solvent includes cyclohexane.

12. The resist coating apparatus of claim 7, further comprising:
a thickness measurement unit measures the thickness of the solvent.

13. The resist coating apparatus of claim 12, wherein
the thickness of the solvent provided by the solvent supply nozzle is measured by the thickness measurement unit before the providing of the resist solution.

14. The resist coating apparatus of claim 7, wherein
the thickness of the solvent is not less than 1 mm.
